(19) United States
(12) Patent Application Publication
(10) Pub. No.: US 2021/0333441 A1
(43) Pub. Date: Oct. 28, 2021

(54) OPTICAL SYSTEM AND PROCESS FOR MANUFACTURING SAME

(71) Applicant: ISORG, Limoges CEDEX 3 (FR)

(72) Inventors: Wilfrid SCHWARTZ, GRENOBLE (FR); Agathe PUSZKA, GRENOBLE (FR); Tindara VERDUCI, GRENOBLE (FR)

(21) Appl. No.: 17/260,961

(22) PCT Filed: Jul. 18, 2019
(86) PCT No.: PCT/EP2019/069455

§ 371 Date: Jan. 15, 2021

(30) Foreign Application Priority Data
Jul. 19, 2018 (FR) 18/56709

(51) Int. Cl. G02B 3/00; G02B 5/20; H01L 27/146

(52) U.S. Cl. CPC G02B 3/0056; G02B 5/201; G06K 9/0004; H01L 27/14685; H01L 27/14627

(57) ABSTRACT

An optical system includes a layer having a first surface intended to receive a radiation and a second surface opposite to the first surface. The the layer is opaque to the radiation and includes through or partially through holes open on the first surface. The optical system further includes an array of micrometer-range optical elements covering the layer. Each optical element is configured to behave as a converging lens having a focal distance in the range from 1 μm to 100 μm. The distance between the surface equidistant from the first and second surfaces and the focal points of the optical elements is smaller than twice the thickness of the layer.

The present patent application claims the priority benefit of French patent application FR18/56709 which is herein incorporated by reference.

### TECHNICAL BACKGROUND

The present disclosure generally concerns optical systems and methods of manufacturing the same.

### PRIOR ART

An optical system is an assembly of optical elements, such as mirrors, lenses, diffraction gratings, etc. enabling to modify the trajectory of the light rays or the properties of light. An example of application of an optical system concerns an image acquisition system where the optical system is interposed between the sensitive portion of an image sensor and the object to be imaged and which enables to form a sharp image of the object to be imaged on the sensitive portion of the image sensor. Another example of application corresponds to the coupling of the optical system to a single photodetector, such as a photodiode, to control the light collected by the photodetector. Another example of application concerns a display or projection system where the optical system covers a light source, for example, a display screen, and enables to modify the radiation emitted by the light source, for example, to angularly filter the radiation emitted by each display pixel.

However, in certain cases, it is not possible to use a conventional optical system. For example, in the case of an image acquisition system, it may not be possible to place a conventional optical system between the sensitive portion of the image sensor and the object to be imaged. This is particularly true when the image sensor occupies a significant surface area, greater than one square centimeter, and the distance between the object to be imaged and the sensitive portion of the image sensor is smaller than one centimeter.

The object to be imaged would then have to be placed at closest to the image sensor so that the image which forms on the sensitive portion of the image sensor is sufficiently sharp. However, there may be a distance between the object and the image sensor, so that the sharpness of the image which forms on the sensitive portion of the image sensor may be insufficient for certain applications, for example, for the capture of fingerprints.

### SUMMARY

There thus is a need for an optical system having a decreased thickness.

Another object of an embodiment is to be able to implement the optical system manufacturing method at an industrial scale.

For this purpose, an embodiment provides an optical system comprising a layer comprising a first surface intended to receive a radiation and a second surface opposite to the first surface, said layer being opaque to said radiation and comprising through or partially through holes open on the first surface, the optical system comprising an array of micrometer-range optical elements covering said layer, each optical element being configured to behave as a converging lens having a focal distance in the range from 1 μm to 100 μm, the distance between the surface equidistant from the first and second surfaces and the focal points of the optical elements being smaller than twice the thickness of said layer.

According to an embodiment, the optical system is configured to block the rays of said radiation having an incidence relative to a direction orthogonal to the first surface in at least a first incidence range and to give way to rays of said first radiation having an incidence relative to a direction orthogonal to the first surface in at least a second incidence range distinct from said at least a first incidence range.

According to an embodiment, the array of micrometer-range optical elements comprises an array of micrometer-range lenses, an array of micrometer-range Fresnel lenses, an array of micrometer-range index gradient microlenses, or an array of micrometer-range diffraction gratings.

According to an embodiment, the array of micrometer-range optical elements comprises an array of micrometer-range lenses.

According to an embodiment, the focal planes of the micrometer-range lenses are confounded.

According to an embodiment, the micrometer-range lenses have a circular or hexagonal base and are arranged according to a hexagonal tiling.

According to an embodiment, the micrometer-range lenses have a square base and are arranged according to a square tiling.

According to an embodiment, the array of micrometer-range optical elements comprises an array of micrometer-range aspherical lenses.

According to an embodiment, each aspherical lens comprises a central portion surrounded with a peripheral portion having a radius of curvature greater than the radius of curvature of the central portion.

According to an embodiment, each lens has a conic constant equal to −1 and a radius of curvature at the center in the range from ⅓ to ⅔ of the pitch of the lenses.

According to an embodiment, the lenses are spherical lenses and the radius of curvature of the lenses is greater than half of pitch of the lenses and smaller than the pitch of the lenses.

According to an embodiment, the system comprises as many micrometer-range optical elements as holes, the pitch between micrometer-range optical elements being the same as the pitch between holes.

According to an embodiment, for each hole, the ratio of the height of the hole, measured perpendicularly to the first surface, to the width of the hole, measured parallel to the first surface, varies from 0.1 to 10.

According to an embodiment, the holes are arranged like the optical elements, the pitch between adjacent holes of a same row or of a same column varying from 1 μm to 500 μm.

According to an embodiment, the height of each hole, measured along a direction orthogonal to the first surface, varies from 0.1 μm to 1 mm.

According to an embodiment, the width of each hole, measured parallel to the first surface, varies from 0.1 μm to 100 μm.

According to an embodiment, the optical system comprises a stack of said layer comprising said through or partially through holes and of an additional layer comprising additional through or partially through holes aligned with said holes.

According to an embodiment, the optical system further comprises a coating covering the array of micrometer-range optical elements, the array of micrometer-range elements being interposed between the coating and said layer, the refraction index of the coating being different from the refraction index of air.

According to an embodiment, the refraction index of the coating is smaller than the refraction index of the array of micrometer-range optical elements.

According to an embodiment, the coating is in full contact with each optical element.

According to an embodiment, the coating is in only contact with each optical element at the top of said optical element, and delimits an air gap with the rest of said optical element.

According to an embodiment, the optical system comprises a support between the array of micrometer-range optical elements and said layer.

According to an embodiment, the refraction index of the support is greater than the refraction index of said layer.

According to an embodiment, the refraction index of the support is greater than the refraction index of the array of micrometer-range optical elements.

According to an embodiment, the holes are filled with a solid, liquid, or gaseous material having a refraction index smaller than the refraction index of the support.

According to an embodiment, the arctangent of the ratio of half the pitch of the micrometer-range optical elements to the thickness of the support is greater than the arcsine of the ratio of the refraction index of the material filling the holes to the refraction index of the support.

According to an embodiment, the holes are tapered.

According to an embodiment, the focal planes of the optical elements are located in the second surface to within 1 μm.

According to an embodiment, for each hole, the dimensions of the hole on the first surface are equal to, or greater, by at most 10%, than the dimensions of the radiation on the first surface focused by the optical element facing the hole.

According to an embodiment, for each hole, the dimensions of the hole on the second surface are equal to or greater, by at least 10%, than the dimensions on the second surface of the radiation focused by the optical element facing the hole.

An embodiment also provides an image acquisition system comprising an image sensor and an optical system such as previously defined covering the image sensor and forming an angular filter.

According to an embodiment, the image sensor comprises an array of photodetectors and the pitch of the optical elements is smaller than half the pitch of the photodetectors.

An embodiment also provides a lighting or display or illumination system comprising a light source and an optical system such as previously defined covering the light source.

According to an embodiment, the light source comprises an area of emission of a radiation located, to within 0.1 μm, in a plane containing the focal points of the optical elements and, for each hole, the ratio of the height of the hole, measured perpendicularly to the first surface, to the width of the hole, measured parallel to the first surface, is greater than 5, whereby the optical system plays the role of a device for collimating the radiation.

### BRIEF DESCRIPTION OF THE DRAWINGS

The foregoing features and advantages, as well as others, will be described in detail in the following description of specific embodiments given by way of illustration and not limitation with reference to the accompanying drawings, in which:

FIG. 1 is a partial simplified cross-section view of an embodiment of an optical system comprising a layer comprising openings and an array of microlenses;

FIG. 2 is a top view of the layer comprising openings of the optical system shown in FIG. 1;

FIG. 3 shows a variant of the optical system of FIG. 1 in the case where the microlenses are embedded in a medium having a refraction index greater than 1;

FIG. 4 shows another variant of the optical system of FIG. 1;

FIG. 5 shows another variant of the optical system of FIG. 1;

FIG. 6 shows another variant of the optical system of FIG. 1;

FIG. 7 shows another variant of the optical system of FIG. 1;

FIG. 8 shows another variant of the optical system of FIG. 1;

FIG. 9 shows another variant of the optical system of FIG. 1;

FIG. 10 shows another variant of the optical system of FIG. 1;

FIG. 11 shows another variant of the optical system of FIG. 1;

FIG. 12 shows a curve of the variation of the transmittance of a layer comprising openings;

FIG. 13 illustrates the optical properties of angular filters having holes of different shapes;

FIG. 14 illustrates other optical properties of the optical system of FIG. 1;

FIG. 15 is a partial simplified cross-section view of an embodiment of an optical system comprising a layer comprising openings and an array of microlenses used for simulations;

FIG. 16 shows a curve of the variation of the normalized angular transmittance obtained with first dimensions and optical parameters for the optical system of FIG. 15;

FIG. 17 shows a curve of the variation of the normalized transmittance obtained with second dimensions and optical parameters for the optical system of FIG. 15;

FIG. 18 shows an embodiment of a microlens arrangement;

FIG. 19 shows another embodiment of a microlens arrangement;

FIG. 20 shows another embodiment of a microlens arrangement;

FIG. 21 comprises, in its left-hand portion, a cross-section view of the optical system of FIG. 1 at the level of a spherical microlens and of an opening of the layer comprising openings and comprises, in its right-hand portion, a top view of the focusing spot obtained with the microlens shown in the left-hand portion;

FIG. 22 is a drawing similar to FIG. 21 for an aspherical lens;

FIG. 23 shows an embodiment of an image acquisition system;

FIG. 24 shows an embodiment of a lighting or projection system;

FIG. 25 illustrates a step of an embodiment of a method of manufacturing the optical system shown in FIG. 3;

FIG. 26 illustrates another step of the method;

FIG. 27 illustrates another step of the method;

FIG. 28 illustrates another step of the method;

FIG. 29 illustrates another step of the method;

FIG. 30 illustrates parameters for obtaining a first hole shape;

FIG. 31 illustrates parameters for obtaining a second hole shape;

FIG. 32 illustrates a step of another embodiment of a method of manufacturing the optical system shown in FIG. 3; and

FIG. 33 illustrates another step of the method.

### DESCRIPTION OF THE EMBODIMENTS

Like features have been designated by like references in the various figures. In particular, the structural and/or functional features that are common among the various embodiments may have the same references and may dispose identical structural, dimensional and material properties.

For the sake of clarity, only the steps and elements that are useful for an understanding of the embodiments described herein have been illustrated and described in detail. In particular, the structure of an image sensor is well known by those skilled in the art and is not described in detail hereafter.

In the following description, when reference is made to terms qualifying absolute positions, such as terms “front”, “rear”, “top”, “bottom”, “left”, “right”, etc., or relative positions, such as terms “above”, “under”, “upper”, “lower”, etc., or to terms qualifying directions, such as terms “horizontal”, “vertical”, etc., unless specified otherwise, it is referred to the orientation of the drawings or to an optical system in a normal position of use.

Unless specified otherwise, the expressions “around”, “approximately”, “substantially” and “in the order of” signify within 10%, and preferably within 5%.

The transmittance corresponds to the ratio of the intensity of the radiation coming out of optical system 5 to the intensity of the radiation entering the optical filter. In the following description, a layer or a film is called opaque to a radiation when the transmittance of the radiation through the layer or the film is smaller than 10%. In the following description, a layer or a film is called transparent to a radiation when the transmittance of the radiation through the layer or the film is greater than 10%. According to an embodiment, for a same optical system, all the elements of the optical system which are opaque to a radiation have a transmittance which is smaller than half, preferably smaller than one fifth, more preferably smaller than one tenth, of the lowest transmittance of the elements of the optical system transparent to said radiation.

Further, in the following description, “useful radiation” designates the electromagnetic radiation crossing the optical system in operation and emitted by a light source associated with the optical system or captured by a detector associated with the optical system. In the following description, “micrometer-range optical element” designates an optical element formed on a surface of a support having a maximum dimension, measured parallel to said surface, greater than 1 μm and smaller than 1 mm. In the following description, a film or a layer is said to be oxygen-tight when the permeability of the film or of the layer to oxygen at 40° C. is smaller than 1·10⁻¹ cm³/(m²*day). The permeability to oxygen may be measured according to the ASTM D3985 method entitled “Standard Test Method for Oxygen Gas Transmission Rate Through Plastic Film and Sheeting Using a Coulometric Sensor”. In the following description, a film or a layer is said to be water-tight when the permeability of the film or of the layer to water at 40° C. is smaller than 1·10⁻¹ g/(m²*day). The permeability to water may be measured according to the ASTM F1249 method entitled “Standard Test Method for Water Vapor Transmission Rate Through Plastic Film and Sheeting Using a Modulated infrared Sensor”. In the following description, the refraction index of a solid, liquid, or gaseous material corresponds to the refraction index of the material for the wavelength range of the useful radiation. Unless specified otherwise, the refraction index is considered as substantially constant over the wavelength range of the useful radiation, for example, equal to the average of the refraction index over the wavelength range of the useful radiation.

According to an embodiment, to increase the sharpness of the image acquired by the image sensor of an image acquisition system in the absence of a complex optical system, a possibility is to cover the image sensor with an optical system having a simple structure, playing the role of an angular filter, comprising an opaque layer crossed by openings, and covered with an array of micrometer-range optical elements, for example, an array of micrometer-range lenses, or microlens, an array of micrometer-range index gradient microlenses, or an array of micrometer-range or nanometer-range diffraction gratings, each micrometer-range or nanometer-range optical element being associated with an opening of the layer comprising openings.

Such embodiment of optical systems will now be described for optical systems comprising an array of micrometer-range optical elements in the case where each micrometer-range optical element corresponds to a micrometer-range lens, or microlens. It should however be clear that these embodiments may also be implemented with other types of micrometer-range optical elements, where each micrometer-range optical element may correspond to a micrometer-range Fresnel lens, to a micrometer-range index gradient lens, or to a micrometer-range diffraction grating.

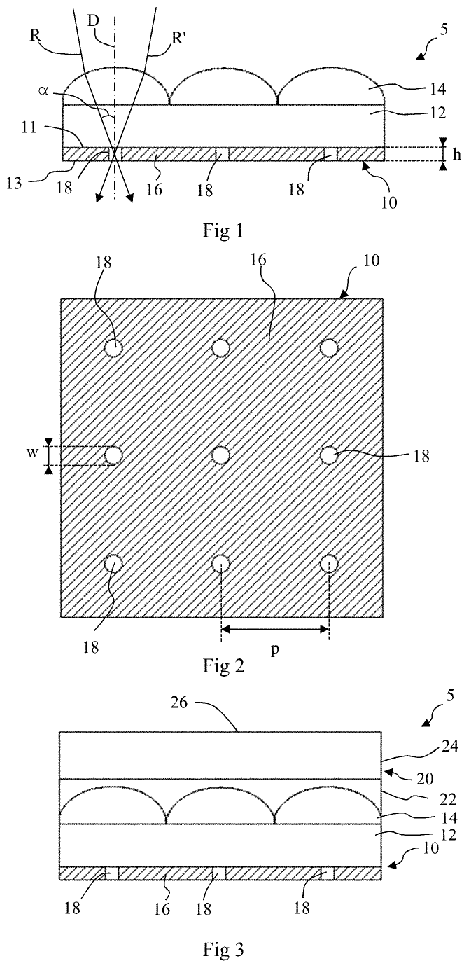

FIG. 1 is a partial simplified cross-section view of an embodiment of an optical system 5. Optical system 5 comprises, from bottom to top in FIG. 1.
a layer 10 comprising openings having upper and lower surfaces 11 and 13, for example, planar and parallel;
an intermediate layer 12 covering layer 10 comprising openings, which intermediate layer 12 may be replaced with an air film; and
an array of micrometer-range optical elements 14, for example, an array of microlenses 14 covering intermediate layer 12, intermediate layer then being capable of playing the role of a support for the array of microlenses 14, where intermediate layer 12 and the array of microlenses 14 may correspond to a monolithic structure.

FIG. 1 shows as an example two rays R and R′ crossing optical system 5. Call initial incidence of radius R the angle between ray R before having crossed microlens 14 and a direction D perpendicular to surface 11, and call final incidence α of ray R the angle between R after having crossed microlens 14 and a direction D perpendicular to surface 11.

FIG. 2 is a top view of the layer 10 comprising openings shown in FIG. 1. In the present embodiment, layer 10 comprising openings comprises an opaque layer 16 crossed by holes 18, also called openings. Preferably, holes 18 are through holes since they extend across the entire thickness of layer 16. According to another embodiment, holes 18 may only extend across a portion of the thickness of opaque layer 16, a residual portion of opaque layer 16 remaining at the bottom of holes 18. However, in this case, the thickness of the residual portion of opaque layer 16 at the bottom of hole 18 is sufficiently low for the assembly comprising hole 18, possibly filled, and the residual portion of opaque layer 16 at the bottom of hole 18 to be able to be considered as transparent to the useful radiation.

According to an embodiment, the distribution of holes 18 follows the distribution of microlenses 14. As an example, FIG. 2 corresponds to the case where the microlenses are distributed in a square mesh. However, other layouts of microlenses 14 are possible, for example, in a hexagonal mesh. Call “h” the thickness of layer 16, which also corresponds to the height of holes 18. Layer 16 is opaque to all or part of the spectrum of the incident radiation. Layer 16 may be opaque to the useful radiation used in operation, for example, absorbing and/or reflective with respect to the useful radiation. According to an embodiment, layer 16 is absorbing in the visible range or a portion of the visible range and/or near infrared and/or infrared. The refraction index of the material forming the array of optical elements 14 is noted n1. The refraction index of the material forming intermediate layer 12 is noted n2. The material forming layer 16 is noted n3. The refraction index of the filling material of holes 18 is noted n4.

In FIG. 2, holes 18 are shown with a circular cross-section. Generally, holes 18 may have any cross-section in top view, for example, circular, oval, or polygonal, particularly, triangular, square, or rectangular according to the manufacturing method used. Further, in FIG. 1, holes 18 are shown with a constant cross-section across the entire thickness of opaque layer 16. However, the cross-section of each hole 18 may vary across the thickness of opaque layer 16. In the case where holes 18 are formed by a method comprising photolithography steps, the hole shape may be adjusted by the method parameters such as the exposure dose, the development time, the divergence of the photolithography exposure source, as well as by the shape of the microlenses.

According to an embodiment, holes 18 are arranged in rows and in columns. Holes 18 may have substantially the same dimensions. Call “w” the width of a hole 18 measured along the row or column direction. Width w corresponds to the diameter of hole 18 in the case of a hole having a circular cross-section. According to an embodiment, holes 18 are regularly arranged along the rows and along the columns. Call “p” the pitch of holes 18, that is, the distance in top view between the centers of two successive holes 18 of a row or of a column. As described in further detail hereafter, the layout of the holes copies the layout of microlenses 14.

Layer 10 comprising openings only gives way to the rays of the incident useful radiation having its final incidence relative to upper surface 11 of layer 10 comprising openings smaller than a maximum final incidence angle αₘₐₓ, which is defined by the following relation (1) in the case where the material forming layer 16 is perfectly absorbing and in the case where the width w of hole 18 at the hole input is identical to the width w of hole 18 at the hole outlet:

tan αₘₐₓ=w/h (1)

The angular aperture “a” of layer 10 comprising openings is equal to twice the maximum final incidence αₘₐₓ. Angular aperture a corresponds to the case of a perfectly absorbing material. For a real material for which the absorption may be smaller than 100%, angular aperture a may be greater than the value obtained from relation (1).

Ratio h/w may vary from 1 to 10, or even be greater than 10. Pitch p may vary from 1 μm to 500 μm, preferably from 1 μm to 100 μm, more preferably from 10 μm to 50 μm, for example, is equal to approximately 15 μm. Height h may vary from 0.1 μm to 1 mm, preferably from 1 μm to 130 μm, more preferably from 10 μm to 130 μm or from 1 μm to 20 μm. Width w may vary from 0.1 μm to 100 μm, preferably from 1 μm to 10 μm, for example, is equal to approximately 2 μm. Holes 18 may all have the same width w. As a variant, holes 18 may have different widths w.

Microlenses 14 are converging lenses, each having a focal distance f in the range from 1 μm to 100 μm, preferably from 5 μm to 50 μm. According to an embodiment, all microlenses 14 are substantially identical. According to an embodiment, the maximum thickness of microlenses 14 is in the range from 1 μm to 20 μm.

The combination of microlenses 14 and of holes 18 enables to optimize two significant parameters. More particularly, this enables to increase the transmittance at normal incidence while decreasing the viewing angle. Without microlenses 14, optimizing these two parameters requires openings having a very low width-to-height ratio and a significant filling factor, which is very difficult to achieve in practice. Adding microlenses 14 on holes 18 enables to release the constraint relative to the form factor of the openings and the filling factor.

FIG. 3 is a cross-section view of a variant of the optical system 5 shown in FIG. 1 where optical system 5 further comprises a coating 20 covering the array of microlenses 14. Coating 20 for example comprises a stack of a plurality of layers, for example, two layers 22 and 24, and comprising an upper surface 26, and coating 20 may be omitted, upper surface 26 then corresponding to the upper surface of the array of microlenses 14. The refraction index of layer 22 is smaller than the refraction index n1 of the array of microlenses 14. As a variation, coating 20 may comprise layer 22 only. The function of layer 22 is to protect microlenses 14 and/or to form a substantially planar surface to simplify the assembly with an upper layer, not shown. Layer 22 preferably has a refraction index smaller than that of microlenses 14 to maintain the focusing effect of microlenses 14. According to an embodiment, the refraction index of layer 22 is in the range from 1.2 to 1.5 and the refraction index of microlenses 14 is in the range from 1.4 to 1.6.

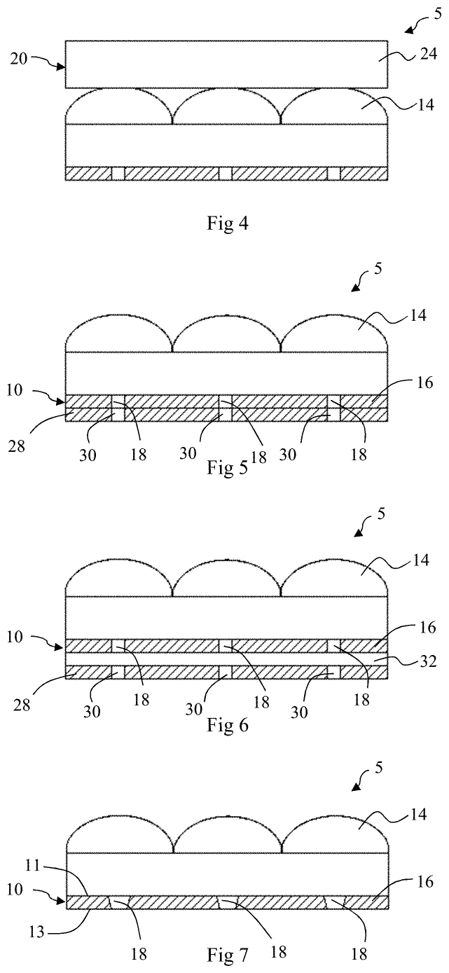

FIG. 4 is a cross-section view of a variant of the optical system 5 shown in FIG. 3 where coating 20 only comprises layer 24, which corresponds to a film applied against the array of microlenses 14. In this case, the contact area between layer 24 and microlenses 14 may be decreased, for example, limited to the tops of microlenses 14. Layer 24 may be used to protect microlenses 14, and/or to form a substantially planar surface to simplify the assembly with an upper layer, not shown. Layer 24 may also be an adhesive layer to assemble optical system 5 to an upper layer.

FIG. 5 is a cross-section view of another variant of the optical system 5 shown in FIG. 1 where layer 10 comprising openings comprises an additional opaque layer 28 covering opaque layer 16, on the side of opaque layer 16 opposite to microlenses 14, and crossed by holes 30 located in line with holes 18.

FIG. 6 is a cross-section view of a variant of the optical system 5 shown in FIG. 5 where layer 10 comprising openings comprises an intermediate layer 32, transparent to the useful radiation, interposed between opaque layers 16 and 28. Generally, layer 10 comprising openings may comprise a stack of more than two opaque layers, each opaque layer being crossed by holes, the opaque layers of each pair of adjacent opaque layers being spaced apart or not by one or a plurality of transparent layers.

FIG. 7 is a partial simplified cross-section view of a variant of the optical system 5 of the embodiment shown in FIG. 1 where the cross-section of holes 18 is not constant. In the embodiment shown in FIG. 7, the cross-section of each hole 18 decreases as the distance to microlenses 14 increases. According to an embodiment, holes 18 have a substantially tapered shape. According to an embodiment, the diameter of holes 18 on the side of surface 11 is in the range from 2 μm to 10 μm and the diameter of holes 18 on the side of surface 13 is in the range from 1 μm to 5 μm.

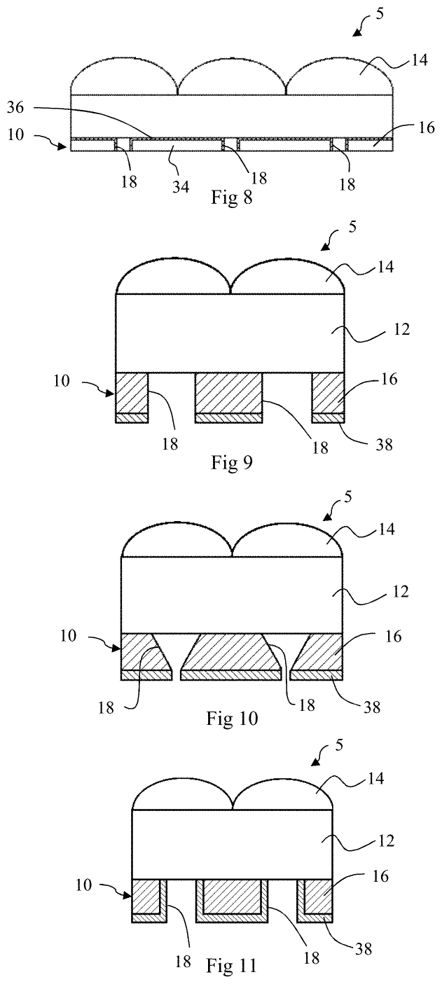

FIG. 8 is a partial simplified cross-section view of a variant of the optical system 5 of the embodiment shown in FIG. 1 where layer 10 comprising openings comprises a base layer 34 made of a first material at least partly transparent to the useful radiation and covered with a coating 36 opaque to the useful radiation, for example, absorbing and/or reflective with respect to the useful radiation. The first material may be a resin. The second material may be a metal, for example, aluminum (Al) or chromium (Cr), a metal alloy, or an organic material. This material may cover the hole walls as shown in FIG. 8 or not according to the characteristics of layer 16.

FIG. 9 is a partial simplified cross-section view of another variant of the optical system 5 of the embodiment shown in FIG. 1 where a layer 38 reflective with respect to the useful radiation covers the surface of layer 10 comprising openings opposite to microlenses 14. In FIG. 9, holes 18 have a shape adapted to microlenses 14, for example substantially cylindrical. Reflective layer 38 may be a metal layer, for example, a layer of aluminum (Al) or of chromium (Cr).

FIG. 10 is a drawing similar to FIG. 9 for holes 18 of tapered shape, the largest diameter of each hole 18 facing microlenses 14.

FIG. 11 is a partial simplified cross-section view of a variant of the optical system 5 of the embodiment shown in FIG. 9 where reflective layer 38 covers the surface of layer 10 comprising openings opposite to microlenses 14 and possibly the inner lateral walls of holes 18.

The embodiments illustrated in FIGS. 9, 10, and 11 advantageously enable to increase the obstruction, either by reflection, or by absorption, of angular filter 5 with respect to the oblique light rays.

According to an embodiment, layer 16 is made of positive resist, that is, resist for which the portion of the resin layer exposed to a radiation becomes soluble to a developer and where the portion of the resist layer which is not exposed to the radiation remains non-soluble in the developer. Opaque layer 16 may be made of colored resin, for example, a colored or black DNQ-Novolack resin or a DUV (Deep Ultraviolet) resist. DNQ-Novolack resins are based on a mixture of diazonaphtoquinone (DNQ) and of a novolack resin (phenolformaldehyde resin). DUV resists may comprise polymers based on polyhydroxystyrenes.

According to another embodiment, layer 16 is made of negative resist, that is, resist for which the portion of the resin layer exposed to a radiation becomes non-soluble to a developer and where the portion of the resist layer which is not exposed to the radiation remains soluble in the developer. Examples of negative resists are epoxy polymer resins, for example, the resin commercialized under name SU-8, acrylate resins, and off-stoichiometry thiol-ene (OSTE) polymers.

According to another embodiment, layer 16 is made of a laser-machinable material, that is, a material capable of degrading under the action of a laser radiation. Examples of laser-machinable materials are graphite, a low-thickness metal film (typically from 50 nm to 100 nm), plastic materials such as poly(methyl methacrylate) (PMMA), acrylonitrile butadiene styrene (ABS), or dyed plastic films such as polyethylene terephthalate (PET), polyethylene naphthalate) (PEN), cyclo olefin polymers (COP), and polyimides (PI).

Further, as an example, layer 16 may be made of black resin absorbing in the visible range and/or in near infrared. According to another example, layer 16 may further be made of colored resin absorbing visible light of a given color, for example, blue, green, or cyan, or infrared light. This may be the case when optical system 5 is used with an image sensor which is only sensitive to light of a given color. This may further be the case when optical system 5 is used with an image sensor which is sensitive to visible light and a filter of the given color is interposed between the image sensor and the object to be detected.

When layer 10 comprising openings is formed of a stack of at least two opaque layers 16, 28, each opaque layer may be made of one of the previously-mentioned materials, and the opaque layers may be made of different materials.

Holes 18, 30 may be filled with air or filled with a solid, liquid, or gaseous material, particularly air, at least partially transparent to the useful radiation, for example polydimethylsiloxane (PDMS). As a variant, holes 18, 30 may be filled with a partially absorbing material to filter the wavelengths of the rays of the useful radiation. Optical system 5 may then further play the role of a wavelength filter. This enables to decrease the thickness of system 5 with respect to the case where a colored filter distinct from optical system 5 would be present. The partially absorbing filling material may be a colored resin or a colored plastic material such as PDMS.

The filling material of holes 18, 30 may be selected to have a refraction index matching with intermediate layer 12 in contact with layer 10 comprising openings and/or to rigidify the structure and improve the mechanical resistance of layer 10 comprising openings, and/or to increase the transmission at normal incidence. Further, the filling material may also be a liquid or solid adhesive material enabling to assemble optical system 5 to another device, for example, an image sensor. The filling material may also be an epoxy or acrylate glue used for the encapsulation of the device having the optical system resting on a surface thereof, for example, an image sensor, considering that layer 12 is an encapsulation film. In this case, the glue fills holes 18 and is in contact with the surface of the image sensor. The glue also enables to laminate optical system 5 on the image sensor.

Intermediate layer 12, which may be omitted, is at least partially transparent to the useful radiation. Intermediate layer 12 may be made of a transparent polymer, particularly of PET, of PMMA, of COP, of PEN, of polyimide, of a layer of dielectric or inorganic polymers (SiN, SiO₂), or of a thin glass layer. As previously indicated, layer 12 and the array of microlenses 14 may correspond to a monolithic structure. Further, layer 12 may correspond to a layer of protection of the device, for example, an image sensor, having optical system 5 attached thereto. If the image sensor is made of organic materials, layer 12 may correspond to a water- and oxygen-tight barrier film protecting the organic materials. As an example, this protection layer may correspond to a SiN deposit in the order of 1 μm on the surface of a PET, PEN, COP, and/or PI film in contact with layer 10 comprising openings. The thickness of intermediate layer 12 or the thickness of the air film when intermediate layer 12 is replaced with an air film is in the range from 1 μm to 500 μm, preferably from 5 μm to 50 μm. In the case where intermediate layer 12 corresponds to a film of a solid material, the thickness of intermediate layer 12 may correspond to the standard thickness of commercially-available films, for example, 12 μm, 19 μm, 23 μm, 36 μm, 50 μm, 100 μm. If other values are desired to be obtained for the distance separating the microlenses 14 of layer with opening 10, a possibility is to form the array of microlenses 14 on a base layer common to all microlenses, the base layer resting on the intermediate layer and enabling to adjust the total thickness of the stack comprising layer 12 and the base layer.

Coating 20 is at least partially transparent to the useful radiation. Coating 20 may have a maximum thickness in the range from 0.1 μm to 10 mm. Upper surface 26 may be substantially planar or have a curved shape.

According to an embodiment, layer 22 is a layer which follows the shape of microlenses 14. Layer 22 may be obtained from an optically clear adhesive (OCA), particularly a liquid optically clear adhesive (LOCA), or a material having a low refraction index, or an epoxy/acrylate glue, or a film of a gas or of a gaseous mixture, for example, air. Preferably, when layer 22 follows the shape of microlenses 14, layer 22 is made of a material having a low refraction index, lower than that of the material of microlenses 14. Layer 22 may be made of a filling material which is a non-adhesive transparent material. According to another embodiment, layer 22 corresponds to a film which is applied against the array of microlenses 14, for example, an OCA film. In this case, the contact area between layer 22 and microlenses 14 may be decreased, for example, limited to the tops of the microlenses. Layer 22 may then be made of a material having a higher refraction index than in the case where layer 22 follows the shape of microlenses 14. According to another embodiment, layer 22 corresponds to an OCA film which is applied against the array of microlenses 14, the adhesive having properties which enable film 22 to completely or substantially completely follow the shape of the surface of the microlenses. According to an embodiment, the refraction index of layer 22 is smaller than the refraction index of microlenses 14. According to an embodiment, layer 24 may be made of one of the materials previously indicated for layer 22. Layer 24 may be omitted. The thickness of layer 24 is in the range from 1 μm to 100 μm.

According to an embodiment, there are as many microlenses 14 as holes 18. Preferably, the layout of microlenses 14 follows the layout of holes 18. In particular, the pitch between the optical centers of adjacent microlenses 14 is the same as the previously-described pitch p of holes 18

According to another embodiment, microlenses 14 may have, in top view, a polygonal base, particularly square, rectangular, pentagonal, or hexagonal. Preferably, microlenses 14 substantially meet, in top view. This advantageously enables to increase the transmission of the filter at normal incidence. According to another embodiment, microlenses 14 may have, in top view, a circular or oval base.

Preferably, the focal planes of microlenses 14 are confounded. The focal planes of microlenses 14 may be located substantially across the thickness of opaque layer 16 or at a distance from opaque layer 16. According to an embodiment, the focal planes of the microlenses are located at a distance from surface 11 in the range from 0 to 1.5 times the thickness h of opaque layer 16. According to an embodiment, the focal planes of the microlenses are located substantially at the level of the lower surface 13 of layer 10 comprising openings, for example, on lower surface 13 to within 1 μm, preferably to within 0.5 μm, more preferably to within 0.1 μm. According to an embodiment, when the cross-section of holes 18 is not constant, the size of the inlet of each hole 18 on the side of surface 11 is equal to or slightly greater than the diameter of the light beam refracted by the microlens in the plane of surface 11 and the size of each hole 18 on the side of surface 13 is equal to or slightly greater than the surface area of the focused light. However, the size of the inlet of each hole 18 on the side of surface 11 may be decreased with respect to what has been described previously to avoid a crosstalk with light originating from neighboring microlenses. Further, the size of each hole 18 on the side of surface may be decreased with respect to what has been previously described to avoid a crosstalk with light originating from neighboring microlenses and/or to decrease the angular aperture of the filter.

According to an embodiment, microlenses 14 all have the same shape. According to another embodiment, microlenses 14 have different shapes. Microlenses 14 may be made of silica, of PMMA, of positive resist, of PET, of PEN, of COP, of PDMS/silicone, of epoxy resin, or of acrylate. Microlenses 14 may be formed by flowing of resist blocks. Microlenses 14 may further be formed by molding, particularly by UV molding or thermal molding, of a layer of PET, PEN, COP, PDMS/silicone or epoxy resin or acrylic polymers.

To increase the transmittance of optical system 5, in the case where the diameter of each hole 18 on the side of surface 11 is equal to the diameter of hole 18 on the side of surface 13, it is preferable for the plane of symmetry of layer 10 comprising openings to be in the focal plane of microlenses 14. The plane of symmetry of layer 10 comprising openings is the plane equidistant from surfaces 11 and 13. The viewing angle “a” of layer 10 comprising openings is selected so that each opening 18 collects the largest number of rays originating from the associated microlens 14 while allowing as little as possible the passage of rays originating from the neighboring lenses. According to an embodiment, aperture angle “a” is selected to be smaller than 2*arctan(D/2f), where D is the diameter of the bases of the microlenses in the case of microlenses having a circular base and, more generally, the largest dimension of the microlens base.

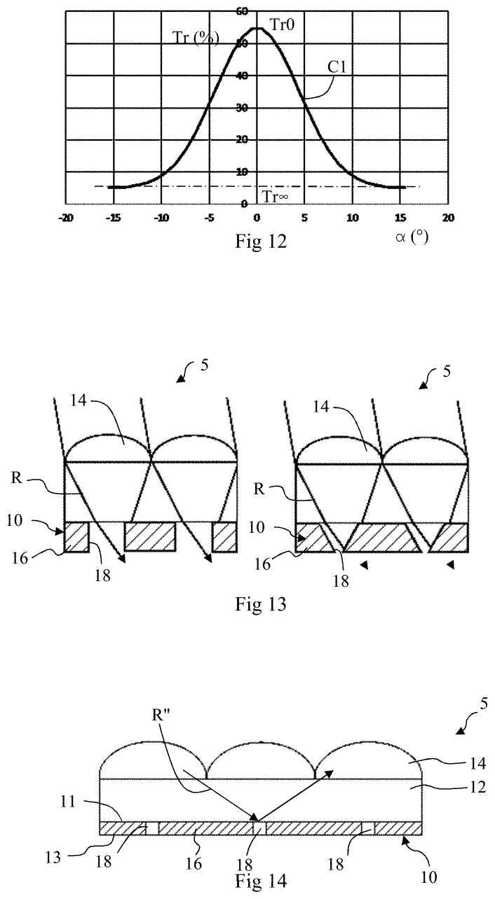

FIG. 12 shows a curve C1 of the variation of the transmittance Tr of an optical system 5 in the absence of the array of microlenses 14 according to the incidence angle α of a collimated incident radiation, the previously-described initial and final incidences then being confounded. The transmittance Tr0 at normal incidence is the transmittance for an incidence a equal to 0°. The transmittance Tr^{∞} at large angles is the limit towards which transmittance Tr tends when incidence α tends towards ±90°. The transmittance Tr^{∞} at large angles is representative of the transparency of the material forming layer 16 by taking into account the fact that the surface reflectivity of layer 16 increases at large angles. In the example illustrated in FIG. 12, the transmittance Tr^{∞} at large angles is substantially equal to 5%. According to an embodiment, the refraction index n3 of layer 16 is smaller than the refraction index n2 of intermediate layer 12. According to another embodiment, the refraction index n3 of layer 16 is greater than the refraction index n2 of intermediate layer 12. For a material completely opaque to the useful radiation, the transmittance Tr^{∞} at large angles is substantially equal to 0%. Call viewing angle (FWHM) the full width at half maximum of curve C1. The crosstalk for a considered opening 18 of optical system 5 is equal to the ratio of the light intensity at the outlet of an opening 18 adjacent to the considered opening to the light intensity which enters the considered opening.

FIG. 13 illustrates the differences in optical properties between the angular filter of FIG. 1, shown in the left-hand portion of FIG. 13 and having cylindrical holes 18, and the angular filter of FIG. 7, shown in the right-hand portion of FIG. 13 and having tapered holes 18. For structures which are besides identical, the decrease in the transmission of light according to the initial incidence of rays R is slower for the angular filter with cylindrical holes than for the angular filter with tapered holes. The angular selectivity of the angular filter with cylindrical holes is thus smaller than the angular selectivity of the angular filter with tapered holes. Generally, the shape of holes 18 may be adapted, in particular according to the desired angular selectivity.

FIG. 14 is a view similar to FIG. 1 illustrating another optical property of optical system 5. According to an embodiment, the crosstalk between neighboring holes 18 is decreased by the selection of the material forming intermediate layer 12 and of the filling material of holes 18 to obtain a total reflection at the interface between intermediate layer 12 and holes 18 for the rays having a high final incidence. To obtain a total reflection at this interface, refraction index n4 should be smaller than refraction index n2. A total reflection is obtained at the interface between intermediate layer 12 and holes 18 for rays having a final incidence greater than a minimum angle of incidence αₘᵢₙ which is defined by relation (2):

αₘᵢₙ=arc sin(n4/n2) (2)

Further, according to an embodiment, to limit the crosstalk between neighboring holes 18, the arctangent of the ratio of half the pitch of microlenses 14 to the thickness of support 12 is greater than αₘᵢₙ.

As an example, the minimum incidence angle αₘᵢₙ is equal to approximately 42° when holes 18 are filled with air (refraction index n4 equal to 1) and intermediate layer 12 is made of PMMA (refraction index n2 equal to 1.48) and the minimum incidence angle αₘᵢₙ is equal to approximately 37° when holes 18 are filled with air and intermediate layer 12 is made of PET (refraction index n2 equal to 1.65). The smaller minimum incidence angle αₘᵢₙ, the larger the number of possible incidences which allow a total reflection. This particularly enables, for a given thickness of intermediate layer 12, to decrease the pitch between neighboring microlenses 14 while decreasing the crosstalk between neighboring holes 18. Further, if refraction index n1 is smaller than refraction index n2, intermediate layer 12 becomes a guiding element for light, which enables to evacuate the light which has not been transmitted through holes 18 on the lateral edges of angular filter 5 after its guiding and attenuation across the thickness of intermediate layer 12.

The transmittance at normal incidence Tr0 particularly depends on the filling factor of microlenses 14, that is, in top view, the ratio of the surface area occupied by the microlenses 14 present on a region to the surface area of this region. Indeed, the decrease of the gaps separating adjacent microlenses 14 enables to increase the transmittance at normal incidence Tr0.

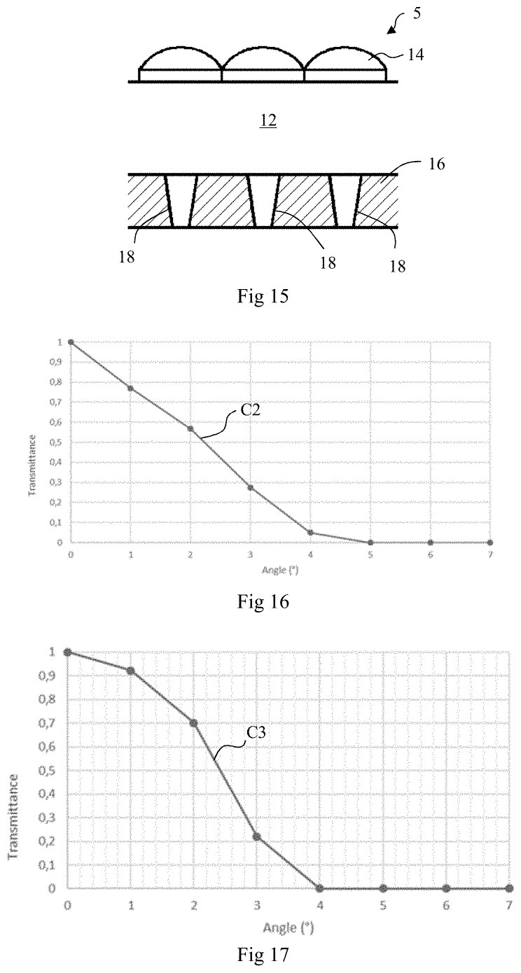

FIG. 15 is a cross-section view of a first optical system 5 according to the configuration shown in FIG. 3 shown and used to make simulations. For first optical system 5, the pitch of microlenses 14 was 20 μm. The array of microlenses 14 comprised a common layer with a 1.5-μm thickness, having the microlenses, with a maximum 6.5-μm thickness, resting thereon. The radius of curvature of microlenses 14 was 11.1 μm. Microlenses 14 are immersed in a medium having a refraction index equal to 1.34, like the medium 22 of FIG. 3. The thickness of intermediate layer 12 was 36 μm. The input diameter of each hole 18 was 8 μm and the output diameter of each hole 18 was 4 μm. The thickness of opaque layer 16 was 15 μm. The inventors have determined by simulation that the obtained transmittance at normal incidence was 60%.

FIG. 16 shows a curve C2 of the variation of the normalized transmittance of the optical system 5 shown in FIG. 15. The viewing angle, defined as being angle at half maximum of the normalized angular transmittance peak, was 2.2°.

A second optical system 5 according to the configuration shown in FIG. 15 has been formed. For second optical system 5, the pitch of microlenses 14 was 12 μm. The array of microlenses 14 comprised a common layer with a 1.5-μm thickness having the microlenses, with a maximum 2-μm thickness, resting thereon. The radius of curvature of microlenses 14 was 9.9 μm. The thickness of intermediate layer 12 was 19 μm. Microlenses are located in a medium having a refraction index equal to 1 as illustrated in FIG. 1. The input diameter of each hole 18 was 5 μm and the output diameter of each hole 18 was 2 μm. The thickness of opaque layer 16 was 10 μm. The inventors have determined by simulation that the obtained transmittance at normal incidence was 64%.

FIG. 17 shows a curve C3 of the variation of the normalized transmittance of the second optical system 5. The viewing angle was 2.4°. The structure of first optical system 5 with a medium 22 of low refraction index enables to avoid the presence of an air gap between microlenses 14 and the portion to be assembled on optical system 5. However, the structure of second optical system with no medium 22 requires an air gap capable of simplifying the manufacturing method and the assembly of optical system 5.

For the simulations previously described in relation with FIGS. 16 and 17, microlenses 14 were spherical, adjacent, and arranged according to a hexagonal tiling. However, a transmittance at normal incidence of approximately 80% may be obtained if a 100% filling factor of the microlenses is used, particularly as described in further detail hereafter.

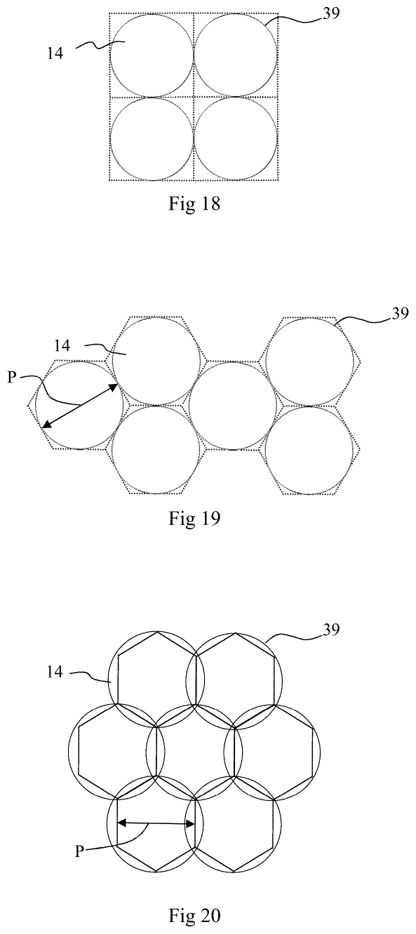

FIG. 18 is a top view of an embodiment of an arrangement of microlenses 14 where each microlens 14 has a circular base. In the present embodiment, microlenses 14 are arranged in rows and in columns according to a square tiling where, except for the periphery of the microlens array, the edge 39 of each microlens 14 is, in top view, inscribed within a square shown in dotted lines, each of these squares having a side common with four other squares. A filling factor of approximately 78% is then obtained.

FIG. 19 is a top view of an embodiment of an arrangement of microlenses 14 where each microlens 14 has a circular base. In the present embodiment, microlenses 14 are arranged according to a hexagonal tiling where, except for the periphery of the microlens array, the edge of each microlens 14 is inscribed, in top view, within a hexagon shown in dotted lines, each of these hexagons having a side common with six other hexagons. Microlenses 14 thus meet substantially only in isolated points. Such an arrangement enables to reach a 90% filling factor, that is, a filling factor much greater than the one that can reached with an arrangement of microlenses 14 of circular base according to a square tiling. In the case where each microlens 14 is substantially spherical, the radius of curvature of the microlens is smaller than the pitch P of microlenses 14.

FIG. 20 is a top view of an embodiment of a layout of microlenses 14 where each microlens 14 has a circular base. In the present embodiment, microlenses 14 are arranged according to a hexagonal tiling where, except for the periphery of the microlens array, the theoretical edge 19 of each microlens 14 is circumscribed to a hexagon, in top view, each of these hexagons having a side common with six other hexagons. There then is a partial overlapping between adjacent microlenses 14. Such an arrangement enables to reach a 100% filling factor, that is, a filling factor greater than that of the hexagonal tiling illustrated in FIG. 19. According to an embodiment, in the case where each microlens 14 is substantially spherical, the radius of curvature of the microlens is greater than half the pitch P of microlenses 14. According to an embodiment, in the case of aspherical microlenses 14, each microlens has a conic constant equal to −1 and a radius of curvature at the center in the range from ⅓ to ⅔ of the pitch of the lenses.

In the previously-described embodiments, each microlens 14 has a circular base. However, microlenses other than microlenses having a circular base may be used. According to an embodiment, microlenses 14 with a square base or a hexagonal base may be used. Such an arrangement enables to reach a filling factor of approximately 100%. It may however not be desirable to obtain too high a filling factor, particularly to decrease the crosstalk of light originating from two neighboring microlenses.

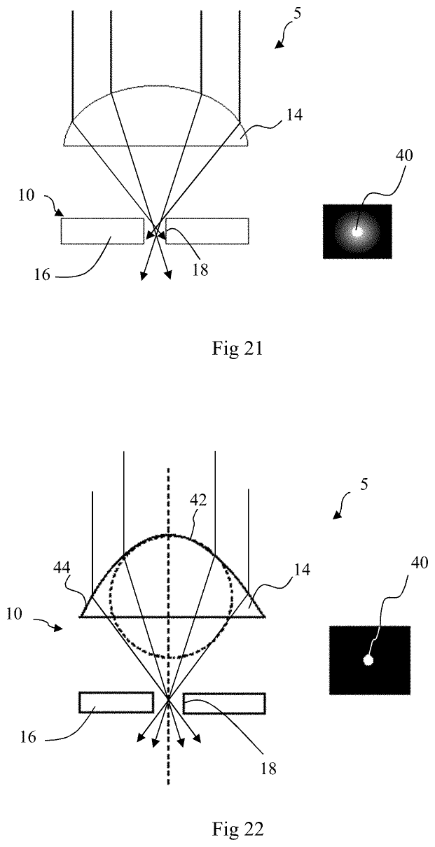

FIG. 21 comprises, in its left-hand portion, a cross-section view of a portion of the optical system 5 of FIG. 1 at the level of a microlens 14 and of an opening 18 of layer 10 comprising openings in an embodiment where microlens 14 is spherical. FIG. 21 further comprises, in its right-hand portion, a top view of the focusing spot 40 obtained with the spherical microlens 14 shown in its left-hand portion. Due to the spherical aberration of microlens 14, the rays of null initial incidence do not all focus on a single point. Focusing spot 40 may then have a blurred contour. Further, this may cause a decrease of the transmittance Tr0 at null incidence really obtained with respect to the theoretical transmittance Tr0 at null incidence since certain rays, particularly those which reach microlens 14 at its periphery, are blocked by layer 10 comprising openings. The angular selectivity is further increased.

FIG. 22 is a drawing similar to FIG. 21 in an embodiment where each microlens 14 is aspherical. Each aspherical microlens 14 may comprise a convex central portion 42 surrounded with a concave or convex peripheral portion 44. Aspherical microlens 14 enables to obtain a sharp focusing spot 40. Further, aspherical microlens 14 enables to increase the transmittance Tr0 at null incidence with respect to the embodiment where the microlens is spherical since aspherical microlens 14 enables to increase the number of rays which are not blocked by layer 10 comprising openings. According to the embodiment, peripheral portion 44 is convex and the radius of curvature of peripheral portion 44 is smaller than the radius of curvature of the convex central portion 42 of microlens 14. Further, aspherical microlens 14 enables to decrease the dimensions of focusing spot 40 with respect to a spherical microlens 14, which enables to decrease the width w of holes 18 and thus to increase the selectivity of the angular filter.

According to an embodiment, a layer of a reflective material may be deposited on the sides of each opening 18. According to another embodiment, a method of roughening the sides of opening 18 may be implemented. It may be a method involving a plasma. According to an embodiment, the arithmetic roughness Ra of the sides of openings 18 is in the range from 10 nm to 1 μm.

An example of application of optical system 5 will now be described for an angular filter of an image acquisition system.

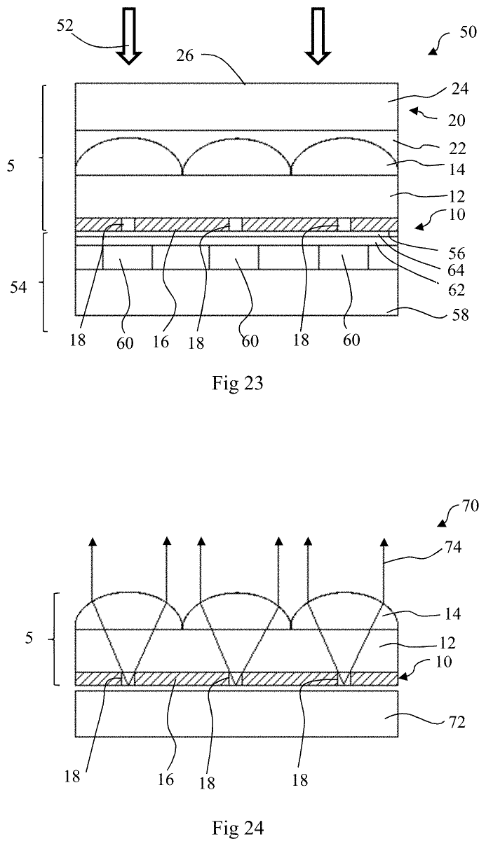

FIG. 23 is a partial simplified cross-section view of an embodiment of an image acquisition system 50 receiving a radiation 52. Image acquisition system 50 comprises, from bottom to top in FIG. 23:
an image sensor 54 having an upper surface 56; and
optical system 5 forming an angular filter and covering surface 56.

According to an embodiment, image sensor 54 comprises, from bottom to top in FIG. 23:
a support 58;
an array of photon sensors 60, also called photodetectors, covering support 58;
an electrically-insulating layer 62 covering photodetector array 60 and interposed between photodetector array 60 and optical system 5 insulating layer 62 delimiting surface 56; and
a transparent layer 64 used as an adhesive between layer 62 and layer 10 comprising openings.

Image sensor 54 further comprises conductive tracks and switching elements, particularly transistors, not shown, enabling to select photodetectors 60. Image acquisition system 50 further comprises means, not shown, for processing the signals output by image sensor 60, for example comprising a microprocessor.

In FIG. 23, the photodetectors are shown as spaced apart by a substantially constant pitch. Photodetectors 60 may be made of organic materials. Photodetectors 60 may correspond to organic photodiodes (OPD), to organic photoresistors. Photodetectors 60 may be made of inorganic materials. Photodetectors 60 may correspond to single-crystal silicon photodiodes associated with an array of CMOS transistors or to amorphous silicon photodiodes associated with an array of CMOS transistors. According to an embodiment, the surface area of image sensor 54 opposite optical system 5 and containing photodetectors 60 is greater than 1 cm², preferably greater than 5 cm², more preferably greater than 10 cm², in particular greater than 20 cm². The upper surface 56 of image sensor 54 may be substantially planar. As a variant, the upper surface 56 of image sensor 54 may be curved.

Layer 62 is transparent to the useful radiation. The thickness of layer 62 is in the range from 10 nm to 50 μm. Layer 62 may be made of at least one of the materials previously described for layers 22 and 24, in particular in the case where layer 24 is an adhesive layer. According to an embodiment, layer 62 is not present. Layer 62 may further be oxygen- and/or water-tight. According to another embodiment, layer 62 is not present and optical system 62 is directly in contact with photodetector array 60.

According to an embodiment, each photodetector 60 is capable of detecting an electromagnetic radiation in a wavelength range from 400 nm to 1,100 nm. All photodetectors 60 may be capable of detecting an electromagnetic radiation in the same wavelength range. As a variation, photodetectors 60 may be capable of detecting an electromagnetic radiation in different wavelength ranges.

Angular filter 5, covering image sensor 54, is capable of filtering incident radiation 52 according to the initial incidence of radiation 52 relative to upper surface 26, particularly so that each photodetector 60 only receives rays having an incidence relative to an axis perpendicular to upper surface 26 smaller than a maximum initial incidence angle smaller than 45°, preferably smaller than 30°, more preferably smaller than 20°, more preferably still smaller than 10, in particular smaller than 5°. Angular filter 5 is capable of blocking the rays of the incident radiation having an initial incidence relative to an axis perpendicular to upper surface 26 greater than the maximum initial incidence angle.

According to an embodiment, photodetectors 60 may be distributed in rows and in columns. In FIG. 23, the pitch of photodetectors 60 is the same as the pitch of holes 18. Layer 10 comprising openings is then preferably aligned with image sensor 54 so that each hole 18 is opposite a photodetector 60. According to an embodiment, the ratio of the area of the cross-section of an opening 18 to the area in top view of the associated photodetector 18 is in the range from 1/10 to ½. According to another embodiment, the pitch p of holes 18 is smaller than the pitch of the photodetectors 60 of image sensor 54, for example, smaller than half the pitch of the photodetectors, preferably smaller than one quarter of the pitch of photodetectors 60. In this case, a plurality of holes 18 may be located opposite a same photodetector 60. According to another embodiment, the pitch p of holes 18 is larger than the pitch of the photodetectors 60 of image sensor 54. In this case, a plurality of photodetectors 60 may be located opposite a same hole 18.

Another example of application of optical system 5 will now be described for a collimation device of a lighting or display system.

FIG. 24 is a partial simplified cross-section view of an embodiment of an illumination system 70 outputting a collimated light. Illumination system 70 comprises, from bottom to top in FIG. 24:
a light source 72 emitting a non-collimated radiation 74; and
the optical system 5 such as previously described, covering light source 72 and receiving the radiation 74 emitted by light source 72, coating 20 being absent from FIG. 24, layer 10 comprising openings being interposed between light source 72 and the array of microlenses 14.

Preferably, the emission plane of light source 72 is closer to the focal plane of optical system 5, preferably located in the focal plane of optical system 5 to within 0.1 μm. Further, according to the envisaged application, the form factor (height-to-width ratio) of the holes 18 of layer 10 is rather high, preferably greater than 5, so that no ray coming out of an opening 18 opposite a given microlens 14 crosses a neighboring microlens. Indeed, in this case, the output ray would not be collimated. As previously mentioned, the aperture angle of layer 10 may be adjusted by the aspect ratio of openings 18.

In the present embodiment, optical system 5 plays the role of a collimation device which enables to collimate the radiation 74 output by light source 72. In FIG. 24, light source 72 is shown with a substantially planar emissive surface. As a variant, the emissive surface of light source 72 may be curved. In FIG. 24, light source 72 is shown as a continuous source extending under optical system 5. It should however be clear that source 72 may comprise separate light sources, and each of the separate light sources may be aligned with one of holes 18.

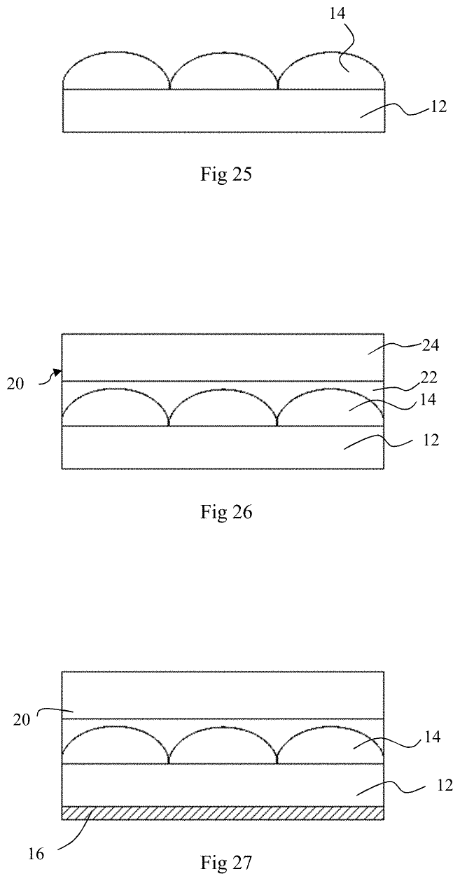

FIGS. 25 to 29 are partial simplified cross-section views of structures obtained at successive steps of another embodiment of a method of manufacturing the optical system 5 shown in FIG. 3.

FIG. 25 shows the structure obtained after the forming of the array of microlenses 14 on intermediate layer 12. As a variant, the array of microlenses 14 may be formed on a support different from intermediate layer 12, this support being removed before the forming of intermediate layer 12 when intermediate layer 12 is present, or before the forming of layer 10 comprising openings when intermediate layer 12 is not present. According to an embodiment, the manufacturing of microlenses 14 comprises the forming of a layer of the material forming microlenses 14 on intermediate layer 12 or another support and the deformation of this layer, for example, by means of an array to form the microlenses. According to another embodiment, microlenses 14 are formed by molding. In FIG. 25, microlenses 14 are shown as being separate or nearly separate and adjacent. As a variant, the array of microlenses 14 may comprise a base layer common to all the microlenses as shown in FIG. 14.

FIG. 26 shows the structure obtained after the forming of coating 20 on the array of microlenses 14 when coating 20 is present. When coating 20 is not present, the steps described hereafter in relation with FIG. 27 may be directly carried out after the steps previously described in relation with FIG. 25. According to an embodiment, the forming of coating 20 may comprise the steps of:
depositing a liquid or viscous layer of the material forming layer 22 on the array of microlenses 14. The liquid layer thus follows the shape of microlenses 14. This layer is preferably self-planarizing, that is, it automatically forms a substantially planar free surface;
curing the liquid layer to form layer 22. This may comprise a step of crosslinking the material forming layer 22, particularly by thermal crosslinking and/or by irradiation by an ultraviolet beam; and
forming layer 24 on layer 22, or in contact with microlens layer 14 when layer 22 is not present, for example, by lamination of a film on layer 22.

FIG. 27 shows the structure obtained after the forming of opaque layer 16 on intermediate layer 12, on the side opposite to the array of microlenses 14. Opaque layer 16 may be deposited by liquid deposition, by cathode sputtering, or by evaporation. Methods such as spin coating, spray coating, heliography, slot-die coating, blade coating, flexography, or silk-screening, may in particular be used. According to the implemented deposition method, a step of drying the deposited material may be provided.

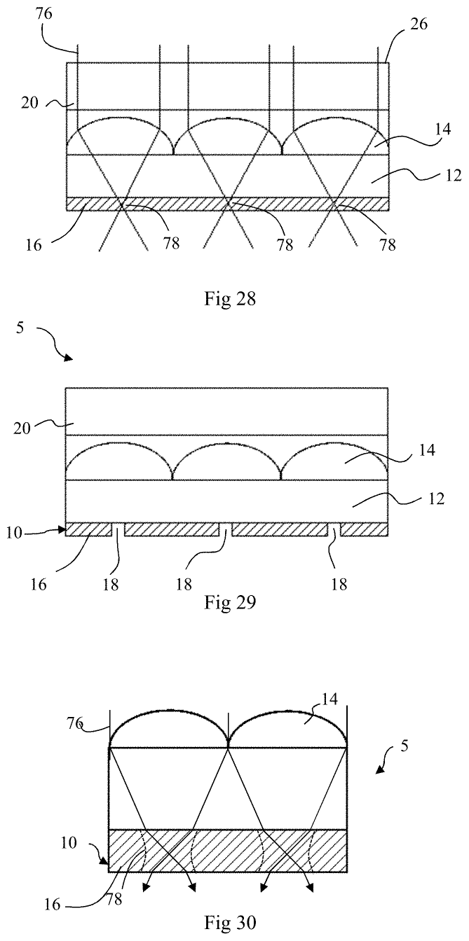

FIG. 28 shows the structure obtained during a step of exposure to a collimated radiation 76, crossing microlenses 14, of portions 78 of opaque layer 16 at the desired locations of holes 18.

FIG. 29 shows the structure obtained during a step of development of opaque layer 16 which has caused the dissolution, in a developer, of the portions 78 of opaque layer 16 exposed to incident radiation 76, thus forming holes 18. Layer 10 comprising openings is thus obtained. The composition of the developer depends on the nature of the positive resist which has been used.

The method may comprise subsequent steps comprising the filling of holes 18 with a filling material.

The radiation used to expose opaque layer 16 depends on the resist used. As an example, radiation 76 is a radiation having wavelengths approximately in the range from 300 nm to 450 nm in the case of a DNQ-Novolack resin or an ultraviolet radiation for a DUV resist. The duration of the exposure of opaque layer 16 to radiation 76 particularly depends on the type of positive resist used and, preferably, is sufficient for the exposed portions 78 of opaque layer 16 to extend across the entire thickness of opaque layer 16;

The exposure of opaque layer 16 is performed through microlenses 14. The shape of the obtained holes 18 particularly depends on the absorption and scattering properties of the material forming layer 16 and on the shape of the incident beam. According to an embodiment, opaque layer 16 is preferably located in the focal plane of microlenses 14 or close to the focal plane of microlenses 14. According to an embodiment, the incident radiation 76 which reaches microlenses 14 is a substantially collimated radiation so that it is focused by each microlens 14 substantially at the level of opaque layer 16 or close to opaque layer 16. Opaque layer 16 may be offset with respect to the focal plane of microlenses 14 to obtain spots of desired dimensions on opaque layer 16 when opaque layer 16 is exposed to a radiation 76 through microlenses 14. Preferably, the inclination of radiation 76 relative to upper surface 26 substantially corresponds to the average inclination formed by the radiation intended to be captured by the photodetectors with upper surface 26 during a normal use of image acquisition system 5. According to an embodiment, radiation 76 is substantially perpendicular to surface 26. According to another embodiment, radiation 76 is inclined with respect to a direction perpendicular to surface 26, thus enabling to obtain holes 18 offset with respect to microlenses 14.

FIG. 30 illustrates an example of shapes of the portions 78 exposed when radiation 76 is strongly scattered by the material forming layer 16 and is focused substantially in the plane of symmetry of layer 16. Substantially cylindrical holes 18, such as shown in FIG. 29, may be obtained, that is, their cross-section is constant.

However, as previously described, the cross-section area of holes 18 may not be constant. As an example, holes 18 may have a tapered shape.

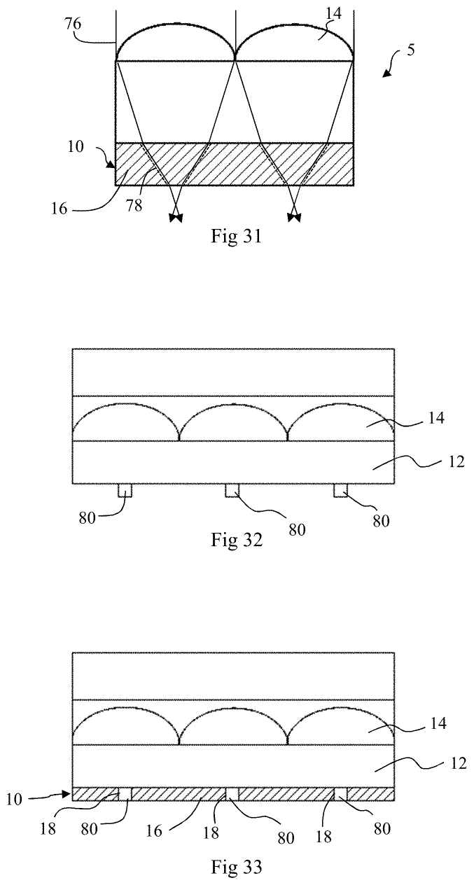

FIG. 31 illustrates an example of shapes of the portions 78 exposed when radiation 76 is lightly scattered by the material forming layer 16 and is focused substantially downstream of layer 16 with respect to microlenses 14. Substantially tapered holes 18, such as shown in FIG. 7, may be obtained.

Generally, the resin development and exposure parameters enable to adjust the profile of the holes. According to another embodiment, incident radiation 76 exhibits a divergence, for example, with a divergence angle greater than 1°, the divergence angle of the incident radiation 76 which reaches microlenses 14 then being adjusted to modulate the width of the holes 18 formed in layer 16.

According to another embodiment, particularly when coating 20 is not present, a layer of a material having an adapted refraction index may be temporarily arranged on the array of microlenses 14 during the exposure step to modify the focal distance of microlenses 14 so that the exposed portions 78 have the desired dimensions.

According to an embodiment, the light source emitting exposure radiation 76, collimated or not, may be displaced with respect to the array of microlenses 14 during the exposure step according to the desired shape of holes 18, for example, by modifying the inclination of the light source with respect to a direction orthogonal to surface 26 and/or by bringing the light source closer to or by drawing it away from the array of microlenses 14. As an example, the light source emitting exposure radiation 76 may be displaced in a loop, which enables to obtain holes 18 having a ring-shaped cross-section. Such a hole shape particularly enables to form a bandpass angular filter authorizing the passage of rays having an initial incidence relative to a direction orthogonal to surface 26 at least in a first incidence range and of giving way to rays having an incidence relative to a direction orthogonal to surface 26 at least in a second incidence range distinct from said at least a first incidence range.

According to an embodiment, microlenses 14 may have different focusing points according to the wavelength of exposure radiation 76. Resist layer 16 may be sensitive to these different wavelengths. As a variant, when layer 10 comprising openings comprises a stack of a plurality of photosensitive layers 16, 28, each photosensitive layer may be sensitive to a radiation at a specific wavelength. The exposure step may then comprise exposing the photosensitive layer or the photosensitive layers to the radiations at these different wavelengths to obtain holes 18, 30 of desired shape.

FIGS. 32 and 33 are partial simplified cross-section views of structures obtained at successive steps of another embodiment of a method of manufacturing the optical system 5 shown in FIG. 3.

The initial steps of the present implementation mode of the manufacturing method comprise the steps previously described in relation with FIGS. 25 to 29, with the difference that layer 16 is replaced with a layer of the material intended to fill the holes 18 of layer 10 comprising openings and is made of negative resist which is, further, transparent to the useful radiation.

FIG. 32 shows the structure obtained during a step of development of the negative resist which has caused the dissolving, in a developer, of the portions of the negative resist layer which have not been exposed to the radiation 76 used during the exposure step, the portions of the negative resist layer exposed at the exposure step thus forming pads 80. The composition of the developer depends on the nature of the negative resist which has been used.

FIG. 33 shows the structure obtained after the forming of opaque layer 16 between pads 80, for example, by spin coating, spray coating, heliography, slot-die coating, blade coating, flexography, or silk-screening. According to an embodiment, the opaque layer is deposited on the entire structure and particularly on pads 80, and the portions of opaque layer covering pads 80 are removed, for example, by steps of photolithography, etching, or lift-off. Pads 80 thus delimit holes 18 in layer 16. Layer 10 comprising openings is thus obtained. According to an embodiment, the implementation of the lift-off method may require, for each pad 80, for the dimensions of the base of pad 80, in contact with layer 12, to be smaller than the dimensions of the top of pad 80. The manufacturing of pads 80 with such a shape may be obtained by providing, during the step of exposure of the negative resist layer previously described in relation with FIG. 32, for the focal planes of microlenses 14 to be located in layer 12.

Another embodiment of a method of manufacturing the optical system 5 shown in FIG. 3 comprises the steps previously described in relation with FIGS. 25 to 29, with the difference that layer 16 is made of a material capable of degrading under the action of radiation 76, particularly when radiation 76 corresponds to a laser radiation. The illumination of this laser radiation is sufficiently low to avoid damaging the array of micrometer-range optical elements 14 and sufficiently high after the collimation by the array of micrometer-range optical elements 14 to degrade layer 16 at the level of portions 78. At the exposure step previously described in relation with FIG. 28, the portions 78 exposed to radiation 76 are thus destroyed by this radiation, then directly forming holes 18. Layer 10 comprising openings is then thus obtained.

According to an embodiment, the method of manufacturing the optical system may correspond to a roll-to-roll method. According to another embodiment, the optical system manufacturing method may correspond to a sheet-to-sheet method.

When layer 10 comprising openings comprises a stack of at least two layers 16, 28, each comprising holes 18, 30, as shown in FIG. 5 or 6, first layer 16 comprising holes 18 is formed first and second layer 28 comprising holes 30 is formed second, taking into account the presence of first layer 16, according to any of the previously-described embodiments of a manufacturing method.

Advantageously, with the previously-described manufacturing method embodiments, the alignment of holes with respect to microlenses 14 is obtained automatically by the very method of forming holes 18. Further, when layer 10 comprising openings comprises a stack of at least first and second opaque layers 16, 28, each comprising holes 18, 30, the alignment of holes 30 of the second opaque layer 28 with respect to the holes 18 of the first opaque layer 16 is obtained automatically by the very method of forming holes 30 of second opaque layer 28.

According to another embodiment of a method of manufacturing the optical system 5 shown in FIGS. 1 and 2, layer 10 comprising openings and the array of microlenses 14 are formed separately and then bonded to each other. In this case, an embodiment of a method of manufacturing layer 10 comprising openings comprises depositing a colored resin layer on a support, printing patterns in the resin layer by photolithography, and developing the resin layer to only keep layer 10 comprising openings. Another embodiment of a method of manufacturing layer 10 comprising openings comprises forming, by photolithography steps, a transparent resin mold having a shape complementary to the desired shape of layer 10 comprising openings, filling the mold with the material forming layer 10 comprising openings, and removing the obtained structure from the mold. Another embodiment of a method of manufacturing layer 10 comprising openings comprises perforating a colored film, for example, a PDMS, PMMA, PEC, COP film. The perforation may be performed by using a micro-perforation tool for example comprising micro-needles to obtain the desired dimensions of holes 18 and pitch of holes 18.

An embodiment of a method of manufacturing the layer 10 comprising openings shown in FIG. 8 comprises the steps of:
deposition of a positive resin layer on a support, for example, by spin coating or by slot die coating;
printing of the patterns of layer 10 comprising openings in the resin layer by photolithography;
development of the resin layer to only keep base layer 34 comprising holes 18; and
forming of coating 36 on base layer 34 and on the lateral walls of holes 18, particularly by a selective deposition, for example, by evaporation, of the second material forming coating 36 only on base layer 34, or by deposition of a layer of the second material forming coating 36 over the entire structure, that is, on base layer 34, on the lateral walls of holes 18, and at the bottom of holes 18, followed by the removal of the second material present at the bottom of holes 18.

Various embodiments and variants have been described. Those skilled in the art will understand that certain features of these various embodiments and variants may be combined, and other variants will occur to those skilled in the art. In particular, the described embodiments of the layers 10 comprising openings shown in FIGS. 5 to 11 may be used with the embodiment of the array of microlenses 14 previously described in relation with FIGS. 18, 19, 21, and 22.

Finally, the practical implementation of the embodiments and variants described herein is within the capabilities of those skilled in the art based on the functional indications provided hereinabove.

1. An optical system comprising a layer comprising a first surface intended to receive a radiation and a second surface opposite to the first surface, said layer being opaque to said radiation and comprising through or partially through holes open on the first surface, the optical system comprising an array of micrometer-range optical elements covering said layer, each optical element being configured to behave as a converging lens having a focal distance in the range from 1 μm to 100 μm, the distance between the surface equidistant from the first and second surfaces and the focal points of the optical elements being smaller than twice the thickness of said layer.

2. The optical system according to claim 1, wherein the optical system is configured to block the rays of said radiation having an incidence relative to a direction orthogonal to the first surface in at least a first incidence range and to give way to rays of said first radiation having an incidence relative to a direction orthogonal to the first surface in at least a second incidence range distinct from said at least one first incidence range.

3. The optical system according to claim 1, wherein the array of micrometer-range optical elements comprises an array of micrometer-range lenses, an array of micrometer-range Fresnel lenses, an array of micrometer-range index gradient microlenses, or an array of micrometer-range diffraction gratings.

4. The optical system according to claim 1, wherein the array of micrometer-range optical elements comprises an array of micrometer-range lenses.

5. The optical system according to claim 4, wherein the focal planes of the micrometer-range lenses are confounded.

6. The optical system according to claim 4, wherein the micrometer-range lenses have a circular or hexagonal base and are arranged according to a hexagonal tiling.

7. The optical system according to claim 4, wherein the micrometer-range lenses have a square base and are arranged according to a square tiling.

8. The optical system according to claim 1, wherein the array of micrometer-range optical elements comprises an array of micrometer-range aspherical lenses.

9. The optical system according to claim 8, wherein each aspherical lens comprises a central portion surrounded with a peripheral portion having a radius of curvature greater than the radius of curvature of the central portion.

10. The optical system according to claim 9, wherein each lens has a conic constant equal to −1 and a radius of curvature at the center in the range from ⅓ to ⅔ of the pitch of the lenses.

11. The optical system according to claim 4, wherein the lenses are spherical lenses and wherein the radius of curvature of the lenses is greater than half the pitch of the lenses and smaller than the pitch of the lenses.

12. The optical system according to claim 1, further comprising as many micrometer-range optical elements as holes, the pitch between micrometer-range optical elements being the same as the pitch between holes.

13. The optical system according to claim 1, wherein, for each hole, the ratio of the height of the hole, measured perpendicularly to the first surface, to the width of the hole, measured parallel to the first surface, varies from 0.1 to 10.

14. The optical system according to claim 1, wherein the holes are arranged like the optical elements, the pitch between adjacent holes of a same row or of a same column varying from 1 μm to 500 μm.

15. The optical system according to claim 1, wherein the height of each hole, measured along a direction orthogonal to the first surface, varies from 0.1 μm to 1 mm.

16. The optical system according to claim 1, wherein the width of each hole, measured parallel to the first surface, varies from 0.1 μm to 100 μm.

17. The optical system according to claim 1, further comprising a stack of said layer comprising said through or partially through holes and an additional layer comprising additional through or partially through holes aligned with said holes.

18. The optical system according to claim 1, further comprising a coating covering the array of micrometer-range optical elements, the array of micrometer-range optical elements being interposed between the coating and said layer, the refraction index of the coating being different from the refraction index of air.

19. The optical system according to claim 18, wherein the refraction index of the coating is smaller than the refraction index of the array of micrometer-range optical elements.

20. The optical system according to claim 18, wherein the coating is in full contact with each optical element.

21. The optical system according to claim 18, wherein the coating is only in contact with each optical element at the top of said optical element, and delimits an air gap with the rest of said optical element.

22. The optical system according to claim 1, further comprising a support between the array of micrometer-range optical elements and said layer.

23. The optical system according to claim 22, wherein the refraction index of the support is greater than the refraction index of said layer.

24. The optical system according to claim 22, wherein the refraction index of the support is greater than the refraction index of the array of micrometer-range optical elements.

25. The optical system according to claim 22, wherein the holes are filled with a solid, liquid, or gaseous material having a refraction index smaller than the refraction index of the support.

26. The optical system according to claim 25, wherein the arctangent of the ratio of half the pitch of the micrometer-range optical elements to the thickness of the support is greater than the arcsine of the ratio of the refraction index of the material filling the holes to the refraction index of the support.

27. The optical system according to claim 1, wherein the holes are tapered.

28. The optical system according to claim 1, wherein the focal points of the optical elements are located in the second surface to within 1 μm.

29. The optical system according to claim 28, wherein, for each hole, the dimensions of the hole on the first surface are equal to, or greater, by at most 10%, than the dimensions of the radiation on the first surface focused by the optical element facing the hole.

30. The optical system according to claim 28, wherein, for each hole, the dimensions of the hole on the second surface are equal to, or greater, by at most 10%, than the dimensions on the second surface of the radiation focused by the optical element facing the hole.

31. An image acquisition system comprising an image sensor and an optical system according to claim 1 covering the image sensor and forming an angular filter.

32. The image acquisition system according to claim 31, wherein the image sensor comprises an array of photodetectors and wherein the pitch of the optical elements is smaller than half the pitch of the photodetectors.

33. A lighting or display or illumination system comprising a light source and an optical system according to claim 1 covering the light source.

34. The lighting or display or illumination system according to claim 33, wherein the light source comprises an area of emission of a radiation located, to within 0.1 μm, in a plane containing the focal points of the optical elements and wherein, for each hole, the ratio of the height of the hole, measured perpendicularly to the first surface, to the width of the hole, measured parallel to the first surface, is greater than 5, whereby the optical system plays the role of a device for collimating the radiation.
